(19) United States
(12) Patent Application Publication
(10) Pub. No.: US 2018/0156545 A1
(43) Pub. Date: Jun. 7, 2018

(54) VAPOR CHAMBER WITH THREE-DIMENSIONAL PRINTED SPANNING STRUCTURE

(71) Applicant: Microsoft Technology Licensing, LLC, Redmond, WA (US)

(72) Inventors: Andrew Douglas Delano, Woodinville, WA (US); Jeffrey Taylor Stellman, Seattle, WA (US); Kurt Allen Jenkins, Sammamish, WA (US); Lincoln M. Ghioni, Redmond, WA (US)

(73) Assignee: Microsoft Technology Licensing, LLC, Redmond, WA (US)

(21) Appl. No.: 15/369,724

(22) Filed: Dec. 5, 2016

(51) Int. Cl. F28D 15/04; F28F 13/00; H05K 7/20

(52) U.S. Cl. CPC F28D 15/046; F28D 15/043; F28F 2255/18; H05K 7/20309; H05K 7/20318; F28F 13/003

(57) ABSTRACT

A three-dimensional printed vapor chamber device is provided. A chamber from a first surface and a second surface at least partially enclosing a volume includes a spanning structure extending from the first surface to the second surface throughout a region within the volume. A defined gap between the first surface and second surface is maintained by the spanning structure, which also defines a plurality of flow passages. Evaporated working fluid flows from an evaporation region proximate a heat source through looped flow passages to a condensation region at a distal end of the chamber before returning as condensate by way of capillary action to the evaporation region.

### BACKGROUND

Vapor chambers are used to draw heat away from heat generating electronic components in many electronic devices. A working fluid within the vapor chamber travels in a loop, evaporating near a heat source and traveling away from the heat source to a condensing region, then returning via capillary action to the heat source. Heat is stored in the working fluid during evaporation, carried by the working fluid, and then dissipated during condensation. In this manner, the electronic device may be cooled. As electronic devices become increasingly smaller and thinner, vapor chambers are subjected to tighter thickness constraints. Manufacturing vapor chambers with small thicknesses presents many challenges, as discussed below.

### SUMMARY

A vapor chamber device is provided. The vapor chamber may include a first surface and a second surface at least partially enclosing a volume and a three-dimensional printed spanning structure extending from the first surface to the second surface throughout a region within the volume and structurally supporting the first surface and second surface so as to maintain a defined gap between the surfaces. The spanning structure also may define a plurality of flow passages. The flow passages may include looped flow passages through which evaporated working fluid flows from an evaporation region proximate a heat source in an outbound flow to a condensation region and in which condensed working fluid flows in an inbound flow from the condensation region to the evaporation region.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a top view showing a vapor chamber within an electronic device directing heat from the electronic components.

FIG. 2 is a section view showing the device of FIG. 1 taken along a line perpendicular to the width direction through the device.

FIGS. 3-8 are section views of various different implementations of a vapor chamber, each illustrating a differently shaped spanning structure and differently configured flow passages formed therein.

FIG. 9 is a section view of a spanning structure supporting two surfaces of the vapor chamber, where the spanning structure and the second surface are in continuity.

FIG. 10 is a top view of a chain-like spanning structure in one form of a three-dimensional printed mesh with flow passages encompassed by the spanning structure.

FIG. 11 is a top view of a loop-like spanning structure in one form of a three-dimensional printed mesh with flow passages encompassed by the spanning structure.

FIG. 12 is a flowchart of a method for manufacturing a vapor chamber device, according to one example implementation.

### DETAILED DESCRIPTION

The inventors have recognized certain challenges of manufacturing vapor chambers using conventional methods. Conventional vapor chambers may be formed by diffusion-bonded plates. This presents the difficulty of securing a reliable bond line between the plates that form the chamber. The contact area between the vapor chamber and heat generating electronics may also be prone to deformation, particularly when the plates forming the vapor chamber are thin. A convex surface can form in a lower plate of the vapor chamber positioned on a planar top of the heat generating electronics, such that a gap is formed between the two, resulting in less efficient heat transfer from the heat generating electronics to the vapor chamber. Further, when developing vapor chambers for compact devices, the interior of the vapor chamber, which is under vacuum, can be placed under considerable compression force by atmospheric pressure. This can lead to deformation and structural failure and a resultant loss of ability to dissipate heat, which in turn can lead to heat-induced damage to an electronic device.

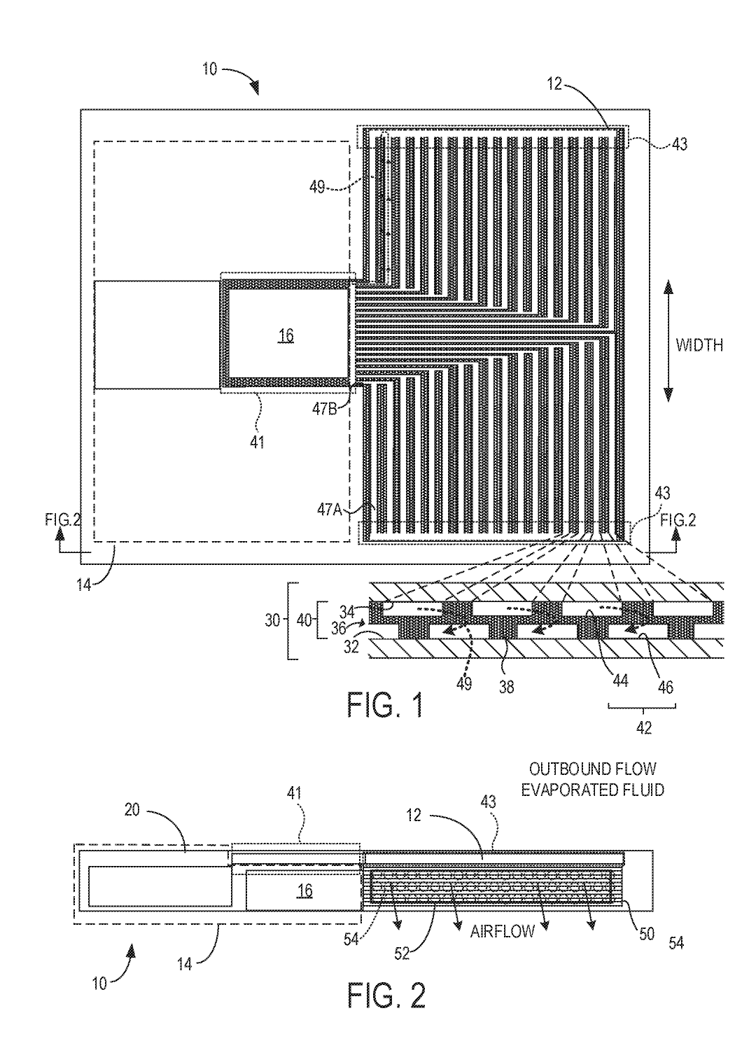

To address these challenges recognized by the inventors and discussed above, FIG. 1 schematically illustrates an electronic device 10 including a vapor chamber device 12 adjacent a heat generating electronic component 14, which may be, for example, a processor 16 such as a CPU or GPU or other electronic component such as a display 20. Vapor chamber device 12 includes a chamber 30 including a first surface 32 and a second surface 34 at least partially enclosing a volume 36 that defines the chamber 30. The first surface 32 and second surface 34 are typically upper and lower planar interior surfaces of the chamber 30, respectively, with the heat source typically positioned below the lower surface, although other configurations of the first and second surfaces are possible.

As viewed from the top in FIG. 1, a three-dimensional printed spanning structure 38 extending from the first surface 32 to the second surface 34 throughout a region within the volume 36 provides a supporting structural mechanism for the vapor chamber device 12. The vapor chamber device 12 operates to transfer a heat load from the first surface 32 and/or second surface 34, via a working fluid within the vapor chamber device 12 interior, continuously drawing heat away from the heat generating electronic component 14 in the electronic device 10. The vapor chamber device 12 may be three-dimensionally printed, which provides the advantageous flexibility of being able to form the vapor chamber in a shape that can be accommodated within any number of differently sized spaces within the electronic device 10.

The spanning structure 38 additionally structurally supports the first surface 32 and second surface 34 so as to maintain a defined gap 40 between them. This support maintains the chamber volume 36, which is under vacuum, resisting against the compressive force of the atmosphere. Such structural support provided by the spanning structure throughout the area of the vapor chamber enables the vapor chamber to be formed thin and wide, in a platy shape, as illustrated, without risk of deformation under compressive force of atmosphere. As it is possible to form the vapor chamber device 12 with a smaller thickness using a spanning structure 38 as compared to conventional vapor chambers that do not have such a support, the vapor chamber device 12 can be accommodated within a thinner electronic device 10 as compared to prior devices.

The magnified portion of FIG. 1 shows a detailed view of a cross section of the spanning structure 38 also defining a plurality of flow passages 42. The three-dimensional printed structural support of the spanning structure 38 may be provided by either filling substantially the entirety of the volume 36 with flow passages 42 or printing the spanning structure 38 only on selected locations of the surfaces.

The vapor chamber device 12 may include a working fluid within the volume 36. Proximate a heat source such as a processor 16, the working fluid in liquid form evaporates within the vapor chamber device 12. The resulting vapor moves along the flow passages 42 of the vapor chamber device 12 away from the heat source until it condenses at the cooler distal end of the chamber, drawing heat away from the heat generating electronic component 14. The three-dimensional printed spanning structure 38 therefore can be constructed with looped flow passages 42 through which evaporated working fluid flows from an evaporation region 41 proximate a heat source in an outbound flow. At a condensation region 43 at a distal end from the heat source the working fluid condenses and flows in an inbound flow from the condensation region 43 to the evaporation region 41.

The looped flow passages 42 may include outbound flow passages 44 through which evaporated working fluid flows and inbound flow passages 46 through which condensed working fluid flows, as shown in the magnified portion of FIG. 1. The outbound flow passages 44 may be fluidically connected to the inbound flow passages 46 at the condensation region 43 at the distal end of the chamber. From this condensation region 43, the condensed vapor returns in liquid form by way of capillary action to the evaporation region 41 of the vapor chamber device 12 proximate the heat source. The inbound flow passages 46 may be fluidically connected to the outbound flow passages 44 at the evaporation region 41 proximate the heat source. In this manner, the outbound flow passages 44 and the inbound flow passages 46 constitute a looped circulation flow path 49 for working fluid that continuously moves heat away from the heat generating electronic component 14 of the electronic device 10 when a heat load is applied.

FIG. 2 presents a section view of the electronic device 10 and vapor chamber device 12, taken at the location indicated in FIG. 1. A looped flow of working fluid circulates under the influence of heat load, between the evaporation region proximate the heat source and the condensation region at the distal end of the vapor chamber device 12. At the condensation region at the distal end of the vapor chamber device 12 a heat sink 50 is situated, which receives heat from the distal end and transfers it to fins having a large surface area over which air flows to carry heat away from the vapor chamber device 12 and out of the electronic device 10. A fan 52 may be placed adjacent the heat sink 50 to induce airflow across the fins of the heat sink and out of the electronic device 10 through air passages 54 in a housing of the electronic device 10, for more powerful cooling.

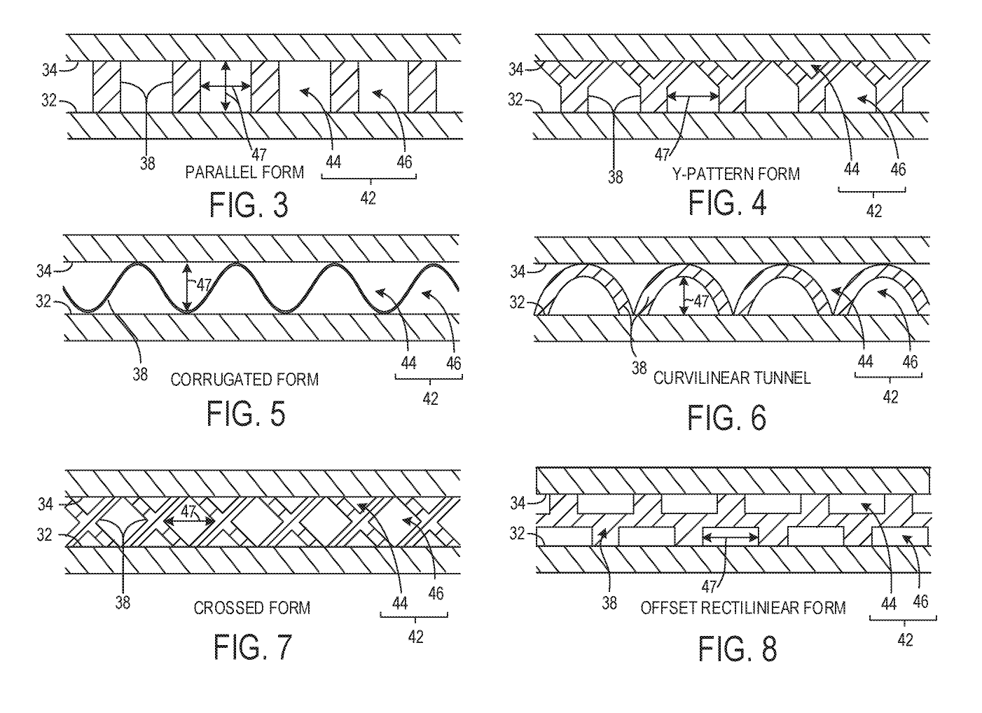

The second surface 34 may be structurally attached to with the spanning structure 38 as depicted in FIGS. 3-8. The spanning structure 38 may include a repeated pattern within the volume 36 of the chamber. Example patterns are illustrated in cross-section in FIGS. 3-8, as repeating columns, repeating sinusoidal curves, repeating X shapes, repeating Y shapes, repeating U shapes, and a repeating brick like pattern. The pattern may repeat in both the width and length dimensions as viewed from the top (i.e., the perspective of FIG. 1). Alternatively, the spanning structure 38 may consist of a non-repeated pattern and be either symmetric or asymmetric. The particular example of FIG. 1 includes a pattern of branching flow paths that is symmetrical about a longitudinal axis of the vapor chamber device 12.

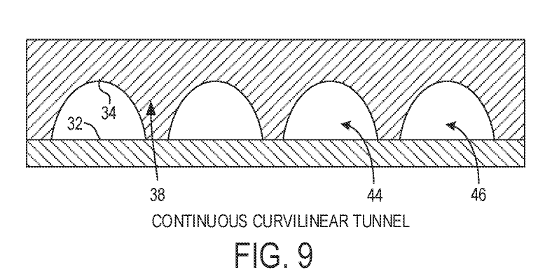

The second surface 34 may be printed in continuity with the spanning structure 38 and thus the second surface 34 may be integrally formed with the spanning structure 38, as depicted in FIG. 9. One potential advantage of this configuration is that the spanning structure 38 and second surface 34 do not have to be bonded or otherwise secured to each other. This configuration can thus be formed simply, with improved structural integrity and heat transfer properties.

The spanning structure 38 that defines a plurality of flow passages 42 may have an internal dimension 47 of 100 to 300 microns to promote capillary flow, and in one particular embodiment may have an internal dimension of 150-250 microns. The internal dimension is typically the overall width or diameter of the flow passage. In the case of a flow passage 42 with a rectangular cross section, both cross sectional dimensions (width and height) may be from 100 to 300 microns, or from 150-250 microns. The internal dimension may decrease with distance from the evaporation region proximate the heat source. Thus, the internal dimension at 47A in FIG. 1 may be smaller than the internal dimension at 47B. It will be appreciated that the cross sectional area of the flow passages 42 is typically from about 10 to 90 mm², and in particular is about 22.5 to 62.5 mm².

Non-structural material remaining after adding the spanning structure 38 by three-dimensional printing may be used internal to the chamber 30 to promote capillary flow. The three-dimensional printing process is advantageous for creating this feature in the vapor chamber device 12. After the printing process, partially sintered material may be partially attached to the structure, creating a texture on the surface of the structure that promotes capillary flow. Additionally, loose material such as printing powder that is not thoroughly removed by cleaning may have a similar potential advantage.

The flow passages 42 may be formed in a variety of configurations in the spanning structure 38, as depicted in section view in FIGS. 3-8. The looped circulation flow of working fluid that continuously moves heat away from the heat generating electronic component 14 moves through the flow passages 42. The looped circulation flow may travel outward away from the heat source in a first set of flow passages 42 and return following cooling to the heat source via a second set of flow passages 42. Alternatively, in some configurations, fluid may travel both outwardly away from the heat source, and inwardly returning from cooling in the same flow passage 42, such as when vapor travels near a top of the flow passage 42 and liquid returns via capillary action along a bottom of a flow passage 42. Further, depending on conditions of use such as temperature, the same vapor chamber may operate with both of the preceding types of looped flows.

In the illustrated example implementation of FIG. 1, the spanning structure 38 within the volume 36 defines a structure of outbound flow passages 44 and inbound flow passages 46. The passages 44, 46, provide space for outbound flow of evaporated working fluid and surfaces for inbound flow of condensed working fluid flowing by way of capillary action. The spanning structure 38 in FIG. 3 has spaces and surfaces in a parallel form defining the flow passages 42. FIG. 4 includes a Y-pattern form defining the flow passages 42. FIG. 5 shows spaces and surfaces of the flow passages 42 in a corrugated form of the spanning structure 38. A curvilinear tunnel form is shown in FIG. 6 that depicts the second surface 34 as structurally attached to the spanning structure 38. This form is also shown as printed in continuity with the second surface 34 in FIG. 9, where the flow passages 42 are similarly formed. The spanning structure 38 in FIG. 7 has a crossed form that defines spaces and surfaces of the flow passages 42. FIG. 8 shows the spanning structure 38 as an offset rectilinear form that includes rectilinear flow passages 42 patterned between the first surface 32 and the second surface 34 in the volume 36.

Alternatively, any three-dimensional form that is suitable to forming flow passages 42 and providing structural support to the vapor chamber device 12 may be employed. Although only one example of an implementation where the spanning structure 38 is printed in continuity with the second surface 34 is shown in FIG. 9, any of the forms in FIGS. 3-8 may be similarly constructed by printing the spanning structure 38 in continuity with the second surface 34.

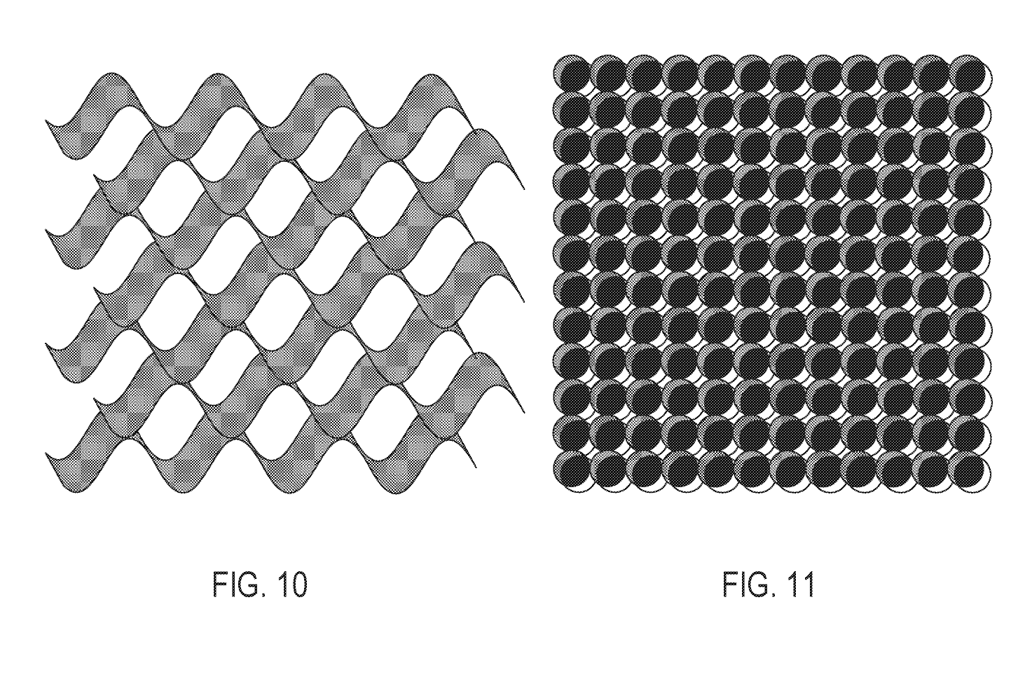

According to the embodiment shown in FIGS. 10 and 11 the spanning structure may also take the form of a three-dimensional printed mesh where the looped flow passages may be encompassed by the mesh. The mesh of FIG. 10 includes a chain-like structure; the mesh of FIG. 11 includes a loop-like structure. It will be appreciated that other forms of a three-dimensional printed mesh may be used, which may include woven or interlocking patterns.

The first surface 32, second surface 34, and spanning structure 38 may be formed by methods appropriate to the material being used. For metals, these methods include direct metal laser sintering (DMLS), selective laser melting (SLM), electron-beam melting (EBM), and screen printing. For plastics, these methods include selective laser sintering (SLS) and stereolithography apparatus (SLA). Other suitable three-dimensional printing methods may also be employed. The surfaces 32, 34 and spanning structure 38 may be formed from a variety of materials. For metal construction, metals that may be used include aluminum, copper, titanium, stainless steel, or a metal alloy. Plastic construction materials may include acrylonitrile butadiene styrene (ABS), polycarbonate, nylon, polyphenylsulfone (PPSF), cyanate ester, urethanes and epoxies. Other construction materials applicable to the three-dimensional printing process may include ceramics such as aluminum oxide and zirconia.

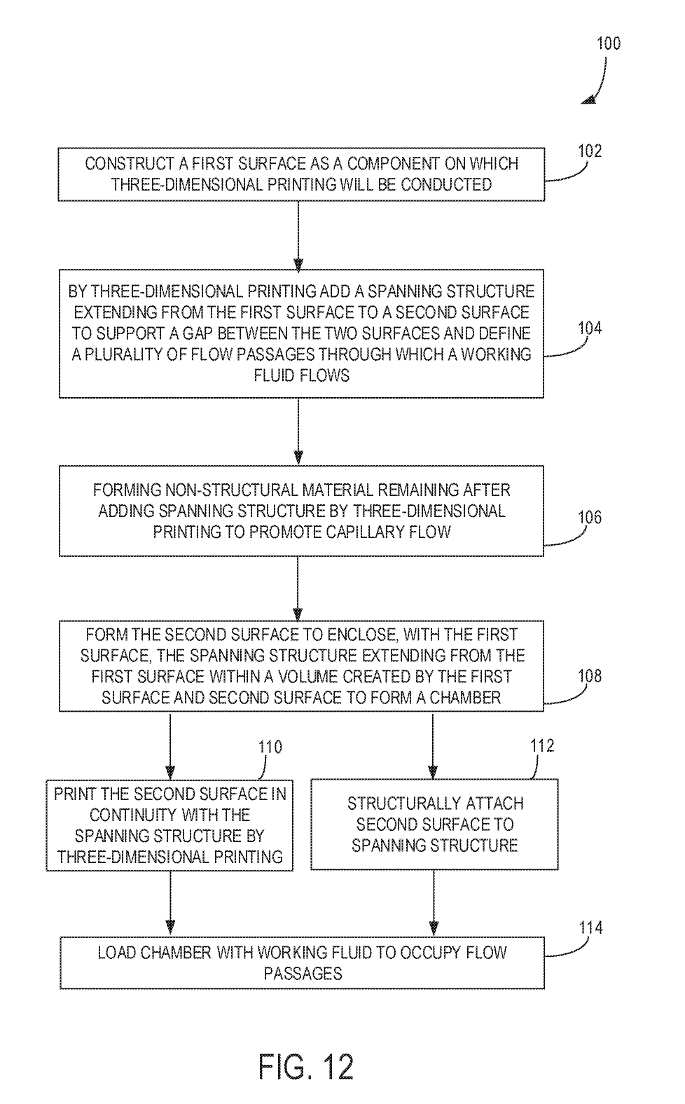

FIG. 12 illustrates a method 100 for manufacturing a vapor chamber device 12 with a spanning structure 38 by three-dimensional printing. At 102, the method includes constructing a first surface 32 as a component on which three-dimensional printing will be conducted. At 104, the method further includes adding, by three-dimensional printing, a spanning structure 38 extending from the first surface 32 that structurally supports a defined gap 40 between the first surface 32 and a second surface 34, the spanning structure 38 also defining a plurality of flow passages 42. As discussed above the flow passages include looped flow passages through which evaporated working fluid flows from an evaporation region proximate a heat source in an outbound flow to a condensation region and in which condensed working fluid flows in an inbound flow from the condensation region to the evaporation region.

The method at 106 further includes forming non-structural material remaining after adding the spanning structure 38 by three-dimensional printing. The remaining non-structural material may include partially sintered powder that may be partially attached to the structure, forming a texture on the structure's surface. Additionally, the non-structural material may be loose material such as printing powder that is not removed by cleaning. The three-dimensional printing process is advantageous for creating this feature in the vapor chamber. Such material internal to the chamber has the potential advantage of promoting capillary flow.

At 108, the method further includes forming the second surface 34 to enclose, with the first surface 32, the spanning structure 38 extending from the first surface 32 within a volume 36 created by the first surface 32 and second surface 34 to form a chamber 30. The method at 110 further includes printing the second surface 34 in continuity with the spanning structure 38. The method at 112 further includes structurally attaching the second surface 34 structurally to the spanning structure 38. The method at 114 may further include loading the flow passages 42 with working fluid.

As detailed above, the spanning structure 38 may be formed by the method to include a repeated pattern within the volume of the chamber. Flow passages 42 may be formed by the method to have an internal dimension of 100 to 300 microns to promote capillary flow. The internal dimension of the flow passages 42 may decrease with distance from the evaporation region proximate the heat source.

As described above, the flow passages 42 in the spanning structure 38 may be formed by the method to have a parallel form, a Y-pattern form, a corrugated form, a curvilinear tunnel form, a crossed pattern, and a rectilinear form repeated on the surfaces and longitudinally offset. The first and second surfaces and spanning structure may be formed by methods including direct metal laser sintering (DMLS), selective laser melting (SLM), electron-beam melting (EBM), screen printing, selective laser sintering (SLS), and stereolithography apparatus (SLA). Suitable materials for construction by three-dimensional printing for vapor chamber device 12 include aluminum, copper, titanium, stainless steel, metal alloy, acrylonitrile butadiene styrene (ABS), polycarbonate, nylon, polyphenylsulfone (PPSF), cyanate ester, urethanes, epoxies, aluminum oxide, zirconia and ceramics.

According to the vapor chamber device 12 configuration as described, heat is drawn away from heat generating electronic components 14. The continual removal of heat during operation of the vapor chamber device 12 is dependent on the looped circulation of working fluid through the flow passages 42. For increasingly thin and compact electronic devices, the operation of the vapor chamber device 12 with an interior under vacuum depends on maintaining structural integrity against atmospheric pressure. The configuration of the vapor chamber device 12 described above with the three-dimensional printed spanning structure 38 that provides structural support while defining flow paths for outbound vapor flow and return liquid flow via capillary action, promotes cooling while retaining sufficient structural stability resist compression by atmospheric forces enabling the vapor chamber device to be manufactured to increasingly small thicknesses.

The following paragraphs provide additional support for the claims of the subject application. One aspect provides a vapor chamber device, comprising a chamber including a first surface and a second surface at least partially enclosing a volume, a three-dimensional printed spanning structure extending from the first surface to the second surface throughout a region within the volume and structurally supporting the first surface and second surface so as to maintain a defined gap therebetween, the spanning structure also defining a plurality of flow passages including looped flow passages through which evaporated working fluid flows from an evaporation region proximate a heat source in an outbound flow to a condensation region and in which condensed working fluid flows in an inbound flow from the condensation region to the evaporation region. In this aspect, additionally or alternatively, the looped flow passage may include outbound flow passages through which evaporated working fluid flows and inbound flow passages through which condensed working fluid flows, the outbound flow passages fluidically connected to the inbound flow passages at the condensation region at a distal end, the inbound flow passages fluidically connected to the outbound flow passages at the evaporation region proximate the heat source. In this aspect, additionally or alternatively, the second surface may be printed in continuity with the spanning structure by three-dimensional printing. In this aspect, additionally or alternatively, the second surface may be structurally attached to the spanning structure. In this aspect, additionally or alternatively, the spanning structure may include a repeated pattern within the volume of the chamber. In this aspect, additionally or alternatively, the spanning structure may include flow passages that have an internal dimension of 100 to 300 microns to promote capillary flow. In this aspect, additionally or alternatively, the internal dimension of the flow passages may decrease with distance from the evaporation region proximate a heat source. In this aspect, additionally or alternatively, the flow passages in the spanning structure may have at least one form selected from the group consisting of a parallel form, a Y-pattern form, a corrugated form, a curvilinear tunnel form, a crossed pattern, and a rectilinear form repeated on the surfaces and longitudinally offset. In this aspect, additionally or alternatively, the first and second surfaces and spanning structure may have been formed by at least one of the group consisting of direct metal laser sintering (DMLS), selective laser melting (SLM), electron-beam melting (EBM), screen printing, selective laser sintering (SLS), and stereolithography apparatus (SLA), and the spanning structure may include at least one of the group consisting of aluminum, copper, titanium, stainless steel, metal alloy, acrylonitrile butadiene styrene (ABS), polycarbonate, nylon, polyphenylsulfone (PPSF), cyanate ester, urethanes, epoxies, aluminum oxide, zirconia and ceramics.

Another aspect provides a method for manufacturing a vapor chamber device, the method comprising constructing a first surface as a component on which three-dimensional printing will be conducted, adding, by three-dimensional printing, a spanning structure extending from the first surface to a second surface throughout a region within a volume structurally supporting the first surface and second surface so as to maintain a defined gap therebetween, the spanning structure also defining a plurality of flow passages including looped flow passages through which evaporated working fluid flows from an evaporation region proximate a heat source in an outbound flow to a condensation region and in which condensed working fluid flows in an inbound flow from the condensation region to the evaporation region, and forming the second surface to enclose, with the first surface, the spanning structure extending from the first surface within a volume created by the first surface and second surface to form a chamber. In this aspect, additionally or alternatively, the looped flow passages may include outbound flow passages through which evaporated working fluid flows and inbound flow passages through which condensed working fluid flows, the outbound flow passages fluidically connected to the inbound flow passages at the condensation region at a distal end and the inbound flow passages fluidically connected to the outbound flow passages at the evaporation region proximate the heat source. In this aspect, additionally or alternatively, the second surface may be printed in continuity with the spanning structure by three-dimensional printing. In this aspect, additionally or alternatively, the second surface may be structurally attached to the spanning structure. In this aspect, additionally or alternatively, the spanning structure may include a repeated pattern within the volume of the chamber. In this aspect, additionally or alternatively, the spanning structure may include flow passages that have an internal dimension of 100 to 300 microns to promote capillary flow. In this aspect, additionally or alternatively, the internal dimension of the flow passages may decrease with distance from the evaporation region proximate a heat source. In this aspect, additionally or alternatively, the flow passages in the spanning structure may have at least one form selected from the group consisting of a parallel form, a Y-pattern form, a corrugated form, a curvilinear tunnel form, a crossed pattern, and a rectilinear form repeated on the surfaces and longitudinally offset. In this aspect, additionally or alternatively, the first and second surfaces and spanning structure may have been formed by at least one of the group consisting of direct metal laser sintering (DMLS), selective laser melting (SLM), electron-beam melting (EBM), screen printing, selective laser sintering (SLS), and stereolithography apparatus (SLA), and the spanning structure may include at least one of the group consisting of aluminum, copper, titanium, stainless steel, metal alloy, acrylonitrile butadiene styrene (ABS), polycarbonate, nylon, polyphenylsulfone (PPSF), cyanate ester, urethanes, epoxies, aluminum oxide, zirconia and ceramics. In this aspect, additionally or alternatively, the method may further comprise forming non-structural material remaining after adding the spanning structure by three-dimensional printing to promote capillary flow.

Another aspect provides a vapor chamber device, comprising a chamber including a first surface and a second surface at least partially enclosing a volume, a three-dimensional printed spanning structure extending from the first surface to the second surface throughout a region within the volume and structurally supporting the first surface and second surface so as to maintain a defined gap therebetween, the spanning structure including a repeated pattern within the volume of the chamber and thereby defining a plurality of flow passages including looped flow passages through which evaporated working fluid flows from an evaporation region proximate a heat source in an outbound flow to a condensation region and in which condensed working fluid flows in an inbound flow from the condensation region to the evaporation region, the internal dimension of the flow passages decreasing with distance from the evaporation region proximate the heat source.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A vapor chamber device, comprising:
a chamber including a first surface and a second surface at least partially enclosing a volume;
a three-dimensional printed spanning structure extending from the first surface to the second surface throughout a region within the volume and structurally supporting the first surface and second surface so as to maintain a defined gap therebetween, the spanning structure also defining a plurality of flow passages including:
looped flow passages through which evaporated working fluid flows from an evaporation region proximate a heat source in an outbound flow to a condensation region and in which condensed working fluid flows in an inbound flow from the condensation region to the evaporation region.

2. The vapor chamber device of claim 1, wherein the looped flow passage include:
outbound flow passages through which evaporated working fluid flows; and
inbound flow passages through which condensed working fluid flows;
wherein the outbound flow passages are fluidically connected to the inbound flow passages at the condensation region at a distal end; and
wherein the inbound flow passages are fluidically connected to the outbound flow passages at the evaporation region proximate the heat source.

3. The vapor chamber device of claim 1, wherein the second surface is printed in continuity with the spanning structure by three-dimensional printing.

4. The vapor chamber device of claim 1, wherein the second surface is structurally attached to the spanning structure.

5. The vapor chamber device of claim 1, wherein the spanning structure includes a repeated pattern within the volume of the chamber.

6. The vapor chamber device of claim 1, wherein the spanning structure includes flow passages that have an internal dimension of 100 to 300 microns to promote capillary flow.

7. The vapor chamber device of claim 1, wherein an internal dimension of the flow passages decreases with distance from the evaporation region proximate a heat source.

8. The vapor chamber device of claim 1, wherein the flow passages in the spanning structure have at least one form selected from the group consisting of a parallel form, a Y-pattern form, a corrugated form, a curvilinear tunnel form, a crossed pattern, and a rectilinear form repeated on the surfaces and longitudinally offset.

9. The vapor chamber device of claim 1, wherein the first and second surfaces and spanning structure have been formed by at least one of the group consisting of direct metal laser sintering (DMLS), selective laser melting (SLM), electron-beam melting (EBM), screen printing, selective laser sintering (SLS), and stereolithography apparatus (SLA); and
wherein the spanning structure includes at least one of the group consisting of aluminum, copper, titanium, stainless steel, metal alloy, acrylonitrile butadiene styrene (ABS), polycarbonate, nylon, polyphenylsulfone (PPSF), cyanate ester, urethanes, epoxies, aluminum oxide, zirconia and ceramics.

10. A method for manufacturing a vapor chamber device, the method comprising:
constructing a first surface as a component on which three-dimensional printing will be conducted;
adding, by three-dimensional printing, a spanning structure extending from the first surface to a second surface throughout a region within a volume structurally supporting the first surface and second surface so as to maintain a defined gap therebetween, the spanning structure also defining a plurality of flow passages including:
looped flow passages through which evaporated working fluid flows from an evaporation region proximate a heat source in an outbound flow to a condensation region and in which condensed working fluid flows in an inbound flow from the condensation region to the evaporation region; and
forming the second surface to enclose, with the first surface, the spanning structure extending from the first surface within a volume created by the first surface and second surface to form a chamber.

11. The method of claim 10, wherein the looped flow passages include:
outbound flow passages through which evaporated working fluid flows; and
inbound flow passages through which condensed working fluid flows;
wherein the outbound flow passages are fluidically connected to the inbound flow passages at the condensation region at a distal end; and
wherein the inbound flow passages are fluidically connected to the outbound flow passages at the evaporation region proximate the heat source.

12. The method of claim 10, wherein the second surface is printed in continuity with the spanning structure by three-dimensional printing.

13. The method of claim 10, wherein the second surface is structurally attached to the spanning structure.

14. The method of claim 10, wherein the spanning structure includes a repeated pattern within the volume of the chamber.

15. The method of claim 10, wherein the spanning structure includes flow passages that have an internal dimension of 100 to 300 microns to promote capillary flow.

16. The method of claim 10, wherein the internal dimension of the flow passages decreases with distance from the evaporation region proximate the heat source.

17. The method of claim 10, wherein the flow passages in the spanning structure have at least one form selected from the group consisting of a parallel form, a Y-pattern form, a corrugated form, a curvilinear tunnel form, a crossed pattern, and a rectilinear form repeated on the surfaces and longitudinally offset.

18. The method of claim 10, wherein the first and second surfaces and spanning structure have been formed by at least one of the group consisting of direct metal laser sintering (DMLS), selective laser melting (SLM), electron-beam melting (EBM), screen printing, selective laser sintering (SLS), and stereolithography apparatus (SLA); and
wherein the spanning structure includes at least one of the group consisting of aluminum, copper, titanium, stainless steel, metal alloy, acrylonitrile butadiene styrene (ABS), polycarbonate, nylon, polyphenylsulfone (PPSF), cyanate ester, urethanes, epoxies, aluminum oxide, zirconia and ceramics.

19. The method of claim 10, further comprising forming non-structural material remaining after adding the spanning structure by three-dimensional printing to promote capillary flow.

20. A vapor chamber device, comprising:
a chamber including a first surface and a second surface at least partially enclosing a volume;
a three-dimensional printed spanning structure extending from the first surface to the second surface throughout a region within the volume and structurally supporting the first surface and second surface so as to maintain a defined gap therebetween, the spanning structure including a repeated pattern within the volume of the chamber and thereby defining a plurality of flow passages including:
looped flow passages through which evaporated working fluid flows from an evaporation region proximate a heat source in an outbound flow to a condensation region and in which condensed working fluid flows in an inbound flow from the condensation region to the evaporation region, the internal dimension of the flow passages decreasing with distance from the evaporation region proximate the heat source.
